(19) United States
(12) Patent Application Publication
(10) Pub. No.: US 2026/0303083 A1
(43) Pub. Date: Oct. 1, 2026

(54) SEMICONDUCTOR DEVICE

(71) Applicant: ABLIC Inc., Nagano (JP)

(72) Inventors: LaHongPhuc Nguyen, Nagano (JP); Noriyuki HARADA, Nagano (JP); Yuji KOBAYASHI, Nagano (JP)

(73) Assignee: ABLIC Inc., Nagano (JP)

(21) Appl. No.: 19/560,163

(22) Filed: Mar. 9, 2026

(30) Foreign Application Priority Data
Mar. 31, 2025 (JP) 2025-057526

(51) Int. Cl. H03K 17/14; H02J 7/34; H02J 7/64; H03K 17/08

(52) U.S. Cl. CPC H03K 17/145; H02J 7/345; H02J 7/64; H03K 17/08; H02J 2207/50

(57) ABSTRACT

A semiconductor device capable of accurately compensating for a leakage current of an element which changes depending on a temperature environment. The semiconductor device includes: a current generation circuit configured to generate a charging current to be supplied to a capacitor connected to a connection terminal; and a current compensation circuit including a compensation current generation circuit configured to generate a compensation current which compensates for a leakage current from a compensation target element including one terminal connected to a path formed between an output terminal of the current generation circuit and the connection terminal, the current compensation circuit being configured to supply the generated compensation current to a point of connection to the path.

### CROSS-REFERENCE TO RELATED APPLICATION

This application claims the priority benefit of Japan application serial no. 2025-057526, filed on Mar. 31, 2025. The entirety of the above-mentioned patent application is hereby incorporated by reference herein and made a part of this specification.

### BACKGROUND OF THE INVENTION

### 1. Field of the Invention

The present invention relates to a semiconductor device.

### 2. Description of the Related Art

There has been disclosed setting of a delay time by a capacitor by externally connecting the capacitor to an external terminal of a semiconductor device (see, for example, Japanese Patent Application Laid-open No. 2014-75694).

However, in a case in which the delay time is set by the capacitor by externally connecting the capacitor to the external terminal of the semiconductor device as in the related art described above, the accuracy in setting the delay time varies depending on the temperature environment in use. The reason is because a leakage current from an element including an ESD protection element connected to a charging current path increases or decreases because of a temperature change, thus adversely affecting the charge amount of the capacitor.

### SUMMARY OF THE INVENTION

The present invention has been made to solve the above-mentioned problem, and provides a semiconductor device capable of accurately compensating for a leakage current of an element which changes depending on a temperature environment.

In order to solve the above-mentioned problem, according to at least one embodiment of the present invention, there is provided a semiconductor device including: a current generation circuit configured to generate a charging current to be supplied to a capacitor connected to a connection terminal; and a current compensation circuit including a compensation current generation circuit configured to generate a compensation current which compensates for a leakage current from a compensation target element including one terminal connected to a path formed between an output terminal of the current generation circuit and the connection terminal, the current compensation circuit being configured to supply the compensation current to a point of connection to the path.

According to the at least one embodiment of the present invention, it is possible to accurately compensate for the leakage current of the element which changes depending on the temperature environment.

### BRIEF DESCRIPTION OF THE DRAWINGS

FIG. 1 is a schematic diagram for illustrating a configuration example of a semiconductor device according to at least one embodiment of the present invention.

FIG. 2 is a schematic diagram for illustrating a first configuration example of a compensation current generation circuit of the semiconductor device according to the at least one embodiment.

FIG. 3 is a schematic diagram for illustrating a second configuration example of the compensation current generation circuit of the semiconductor device according to the at least one embodiment.

FIG. 4 is a schematic diagram for illustrating a third configuration example of the compensation current generation circuit of the semiconductor device according to the at least one embodiment.

FIG. 5 is a schematic diagram for illustrating a fourth configuration example of the compensation current generation circuit of the semiconductor device according to the at least one embodiment.

### DESCRIPTION OF THE EMBODIMENTS

Now, a semiconductor device according to at least one embodiment of the present invention is described with reference to the drawings.

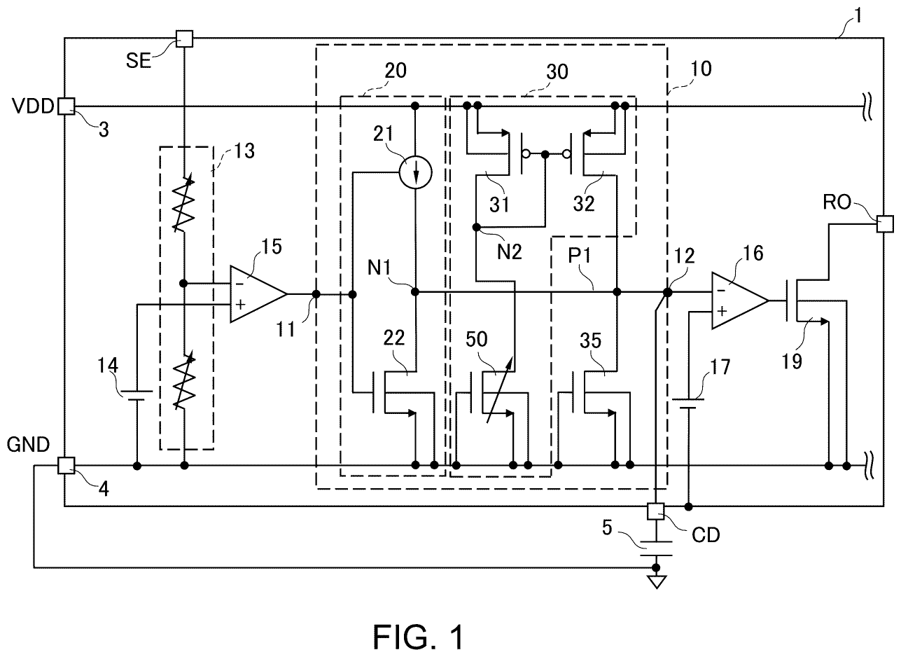

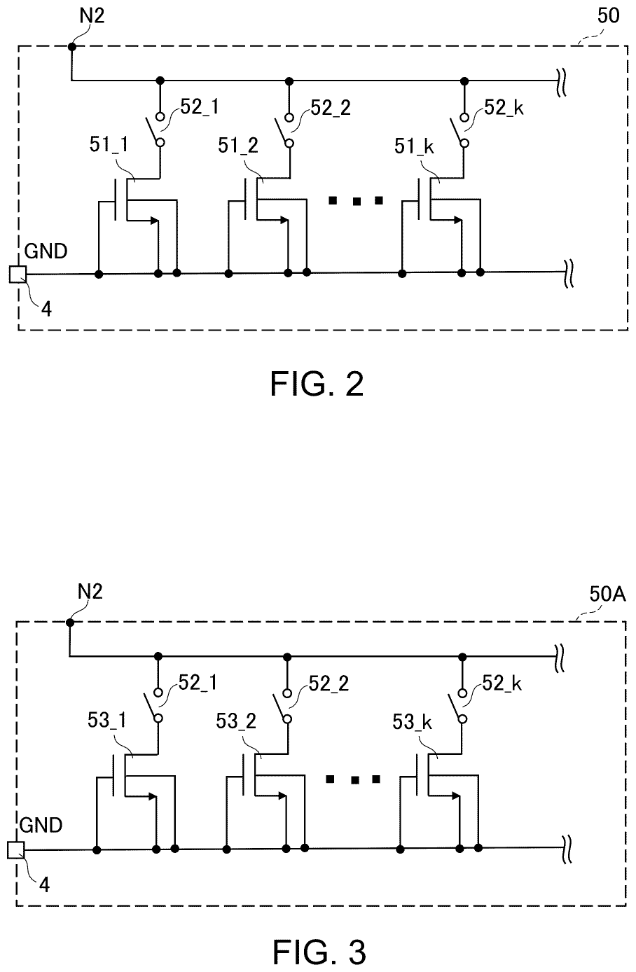

FIG. 1 is a schematic diagram for illustrating a configuration example of a semiconductor device 1 which is an example of the semiconductor device according to the at least one embodiment. Further, FIG. 2 is a schematic diagram for illustrating a configuration of a compensation current generation circuit 50 which is a first configuration example of a compensation current generation circuit of the semiconductor device according to the at least one embodiment.

The semiconductor device 1 includes, for example, a current generation circuit 20 for generating a charging current, and a current compensation circuit 30 which includes the compensation current generation circuit 50 and generates a compensation current. The current generation circuit 20 and the current compensation circuit 30 form a delay circuit 10 for supplying the charging current. The semiconductor device 1 includes, as terminals connected to the outside, a VDD terminal 3, a GND terminal 4, a sense terminal SE, a reset terminal RO, and a connection terminal CD. The semiconductor device 1 further includes, on an input terminal 11 side of the delay circuit 10, a voltage dividing circuit 13, a reference voltage source 14, and a comparator 15, and includes, on an output terminal 12 side of the delay circuit 10, a comparator 16, a reference voltage source 17, and an NMOS transistor 19 which is an output transistor.

The VDD terminal 3 is a power supply terminal for receiving supply of a power supply voltage VDD. The GND terminal 4 is a power supply terminal for receiving supply of a ground voltage which is an example of a power supply voltage different from the power supply voltage VDD. The connection terminal CD is grounded through a capacitor 5. The sense terminal SE is connected to a voltage monitoring target located outside. The reset terminal RO is connected to a pull-up resistor (not shown) and is connected to a drain of the NMOS transistor 19.

The voltage dividing circuit 13 is a resistance voltage dividing circuit formed by connecting a plurality of resistors, such as two resistors, in series. The voltage dividing circuit 13 includes a first terminal connected to the sense terminal SE, a second terminal connected to the GND terminal 4, and an output terminal which is a connection point between the resistors forming the voltage dividing circuit 13 and at which a divided voltage appears. The comparator 15 includes an inverting input terminal (−) connected to the output terminal of the voltage dividing circuit 13, a non-inverting input terminal (+) connected to a first terminal of the reference voltage source 14, and an output terminal connected to the input terminal 11 of the delay circuit 10. A second terminal of the reference voltage source 14 is connected to the GND terminal 4.

The comparator 16 includes an inverting input terminal (−) connected to the output terminal 12 of the delay circuit 10, a non-inverting input terminal (+) connected to a first terminal of the reference voltage source 17, and an output terminal connected to a gate of the NMOS transistor 19. A second terminal of the reference voltage source 17 is connected to the GND terminal 4. A source and a back gate of the NMOS transistor 19 are connected to the GND terminal 4.

The current generation circuit 20 includes a current source 21 including a first terminal connected to the VDD terminal 3, a second terminal, and a control terminal connected to the input terminal 11 of the delay circuit 10, and an NMOS transistor 22 including a drain connected to the second terminal of the current source 21, a gate connected to the input terminal 11, and a source and a back gate connected to the GND terminal 4. A node N1 which is a connection point between the second terminal of the current source 21 and the drain of the NMOS transistor 22 corresponds to an output terminal of the current generation circuit 20.

The current compensation circuit 30 includes the compensation current generation circuit 50 for generating a compensation current for compensating for a leakage current from an ESD protection element 35 and the NMOS transistor 22. The ESD protection element 35 serves as a compensation target element connected to a path P1 formed between the node N1 and the connection terminal CD. As illustrated in, for example, FIG. 1 and FIG. 2, the compensation current generation circuit 50 includes “k” current compensation transistors 51_1, . . . , 51_k connected in parallel between a first terminal corresponding to a node N2 in the current compensation circuit 30 and a second terminal connected to the GND terminal 4. Here, “k” is a natural number of 2 or more, that is, plural.

The current compensation transistors 51_1, . . . , 51_k are each formed of a transistor having the same threshold voltage and a smaller area as compared to the MOS transistor forming the ESD protection element 35. Moreover, the current compensation transistors 51_1, . . . , 51_k are formed to have an overall area that is smaller than an area of the NMOS transistor forming the ESD protection element 35. Further, a drain of each of the current compensation transistors 51_1, . . . , 51_k is connected to the node N2 through a corresponding one of “k” switches 52_1, . . . , 52_k serving switching elements.

The current compensation circuit 30 further includes a current mirror circuit including a PMOS transistor 31 and a PMOS transistor 32. The current mirror circuit duplicates and folds back a compensation current generated by the compensation current generation circuit 50 at a mirror ratio of 1: n (n>1). Further, at least one of the PMOS transistor 31 or the PMOS transistor 32 is formed to enable fine adjustment of the mirror ratio of 1:n. That is, the current mirror circuit in the current compensation circuit 30 is formed with a fine adjustment range of ±α (0<α<1) using the mirror ratio of 1: n as a reference.

Sources and back gates of the PMOS transistor 31 and the PMOS transistor 32 are each connected to the VDD terminal 3. A gate and a drain of the input-side PMOS transistor 31 forming the current mirror circuit are connected to a first terminal of the compensation current generation circuit 50. A point of connection of the gate and the drain of the PMOS transistor 31 to the compensation current generation circuit 50 (more specifically, the first terminal) is the node N2.

A gate of the output-side PMOS transistor 32 forming the current mirror circuit is connected to the gate and the drain of the PMOS transistor 31. A drain of the PMOS transistor 32 is connected to the path P1. The path P1 connects the node N1, a drain of the NMOS transistor which is the ESD protection element 35, the output terminal 12, and the connection terminal CD.

Next, operation of the semiconductor device 1 is described. The semiconductor device 1 monitors a voltage of the voltage monitoring target by monitoring a voltage of the sense terminal SE connected to the voltage monitoring target. The comparator 15 compares the divided voltage of the voltage dividing circuit 13 with the reference voltage supplied from the reference voltage source 14. The comparator 15 supplies a signal having a voltage of a high level (hereinafter referred to as “H level”) in a case in which the divided voltage is equal to or less than the reference voltage supplied from the reference voltage source 14, and supplies a signal having a voltage of a low level (hereinafter referred to as “L level”) in a case in which the divided voltage is higher than the reference voltage.

The current generation circuit 20 supplies the charging current from the node N1, or stops the supply of the charging current, depending on a signal level of a signal provided to the input terminal. The current source 21 and the NMOS transistor 22 operate exclusively. Specifically, in the current source 21 and the NMOS transistor 22, in a case in which a voltage level of the signal provided to the input terminal 11 of the delay circuit 10 corresponding to the input terminal of the current generation circuit 20 is the H level, the current source 21 is in an off state in which the supply of the charging current is stopped, while the NMOS transistor 22 is in an on state. In contrast, in a case in which the voltage level of the signal provided to the input terminal 11 is the L level, the current source 21 is in an on state in which the charging current is supplied from the node N1 to the path P1, while the NMOS transistor 22 is in an off state.

The current compensation circuit 30 compensates for a leakage current component leaking from a transistor including one terminal connected to the path P1 and another terminal connected to the GND terminal 4. The current compensation circuit 30 performs the compensation by causing a compensation current that is based on a current flowing through the compensation current generation circuit 50 to flow through the path P1. A magnitude of the compensation current is adjusted by adjusting a magnitude of the current flowing through the compensation current generation circuit 50 by a connection relationship between the current compensation transistors 51_1, . . . , 51_k and the node N2 and a mirror ratio of the current mirror circuit. In the compensation current generation circuit 50, the current flowing through the compensation current generation circuit 50 and, consequently, the compensation current are finely adjusted by individually switching the “k” switches 52_1, . . . , 52_k between a closed state (on state) in which the “k” switches 52_1, . . . , 52_k are closed and an open state (off state) in which the “k” switches 52_1, . . . , 52_k are open. Further, the compensation current is finely adjusted by the fine adjustment of the mirror ratio of the current mirror circuit.

Here, a leakage current flowing through the ESD protection element 35 which is the main compensation target element is represented by IL35, and currents flowing through the current compensation transistors 51_1, . . . , 51_k are represented by I11, . . . , I1k, respectively. The compensation current generation circuit 50 is formed such that the following Equation (1-1) is satisfied.

$$IL 35 = ( n \pm α ) \cdot ( I 11 + … + I 1 k ) \qquad ( 1 - 1 )$$

Here, n±α represents a finely adjustable mirror ratio.

In a case in which the divided voltage is equal to or less than the reference voltage supplied from the reference voltage source 14, the current source 21 enters the off state and the NMOS transistor 22 enters the on state in response to reception of a signal from the comparator 15. The output terminal 12 of the delay circuit 10 which is the same node as the output terminal of the current generation circuit 20 becomes the voltage of the GND terminal 4, that is, the L level. The voltage of the output terminal 12 supplied to the inverting input terminal (−) of the comparator 16 is lower than the reference voltage supplied from the reference voltage source 17 supplied to the non-inverting input terminal (+) of the comparator 16. Because of this, the comparator 16 supplies an output signal having an H level signal voltage to the gate of the NMOS transistor 19.

The NMOS transistor 19 enters the on state in response to reception of the H level voltage at the gate. Because of this, the reset terminal RO becomes the voltage of the GND terminal 4, that is, the L level. Accordingly, in a case in which the divided voltage is equal to or less than the reference voltage supplied from the reference voltage source 14, the delay time is not generated, and the reset signal is at the L level.

In a case in which the divided voltage exceeds the reference voltage supplied from the reference voltage source 14, the current source 21 enters the on state and the NMOS transistor 22 enters the off state in response to reception of the signal from the comparator 15. That is, the current generation circuit 20 starts the supply of the charging current and starts charging the capacitor 5 connected to the connection terminal CD. In the semiconductor device 1, the charging current supplied to the capacitor 5 is a current in which a leakage current component leaking from the path P1 which is a charging path is compensated for by the current compensation circuit 30. As the charging of the capacitor 5 progresses, the voltage of the connection terminal CD also rises.

In a case in which the voltage of the connection terminal CD exceeds the reference voltage supplied from the reference voltage source 17, the signal voltage of the output signal from the comparator 16 transitions from the H level to the L level. Because of this, the NMOS transistor 19 transitions from the on state to the off state. Because the NMOS transistor 19 is turned off, the voltage of the reset terminal RO transitions from the L level to the H level. Accordingly, in a case in which the divided voltage exceeds the reference voltage supplied from the reference voltage source 14, the delay time is generated, and the reset signal transitions from the L level to the H level after the delay time elapses.

As described above, according to the semiconductor device 1, the semiconductor device 1 includes a compensation current generation circuit 50, 50A, 50B, or 50C which includes a plurality of transistors connected in parallel and is capable of switching the number of the transistors connected in parallel. Because of this configuration, the leakage current of the element which changes depending on the temperature environment can be accurately compensated for. Further, the mirror ratio is finely adjustable in the current mirror circuit included in the compensation current generation circuit 50, 50A, 50B, or 50C. Because of this configuration, fine adjustment is possible in consideration of, for example, the leakage current generated in the off state of the NMOS transistor 22.

According to the semiconductor device 1, the semiconductor device 1 includes the compensation current generation circuit 50 having an area smaller than the area of the ESD protection element 35. Because of this, the compensation current generation circuit 50 can be formed to have a smaller area than that in the related art. Further, the type of the compensation target element is not limited to the ESD protection element 35. The magnitude of the compensation current can be adjusted for supply to various elements.

The present invention is not limited to the above-mentioned at least one embodiment as it is. In an implementation stage, the present invention can be implemented in various forms in addition to the above-mentioned at least one embodiment. Various omissions, additions, substitutions, or modifications can be made without departing from the gist of the invention. For example, the semiconductor device 1 may include the compensation current generation circuit 50A, 50B, or 50C (see FIG. 3 to FIG. 5 to be referred to later) instead of the compensation current generation circuit 50.

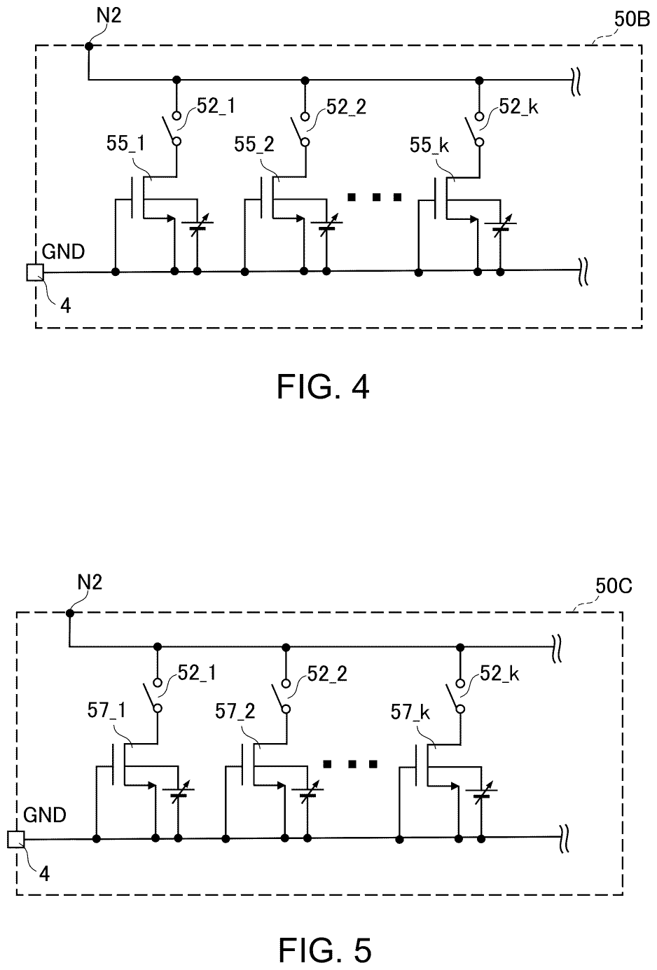

FIG. 3 is a schematic diagram for illustrating a configuration of the compensation current generation circuit 50A which is a second configuration example of the compensation current generation circuit of the semiconductor device according to the at least one embodiment. FIG. 4 is a schematic diagram for illustrating a configuration of the compensation current generation circuit 50B which is a third configuration example of the compensation current generation circuit of the semiconductor device according to the at least one embodiment. FIG. 5 is a schematic diagram for illustrating a configuration of the compensation current generation circuit 50C which is a third configuration example of the compensation current generation circuit of the semiconductor device according to the at least one embodiment.

The compensation current generation circuit 50A differs from the compensation current generation circuit 50 in including current compensation transistors 53_1, . . . , 53_k instead of the current compensation transistors 51_1, . . . , 51_k, but the other points are substantially the same. The current compensation transistors 53_1, . . . , 53_k are formed to have a threshold voltage that is lower than the threshold voltage of the current compensation transistors 51_1, . . . , 51_k, that is, the threshold voltage of the NMOS transistor which is the ESD protection element 35.

The compensation current generation circuit 50B differs from the compensation current generation circuit 50 in including current compensation transistors 55_1, . . . , 55_k instead of the current compensation transistors 51_1, . . . , 51_k, but the other points are substantially the same. A variable voltage source is connected between a source and a back gate of each of the current compensation transistors 55_1, . . . , 55_k to set a desired potential difference therebetween, as compared to the current compensation transistors 51_1, . . . , 51_k.

The compensation current generation circuit 50C differs from the compensation current generation circuit 50A in including current compensation transistors 57_1, . . . , 57_k instead of the current compensation transistors 53_1, . . . , 53_k, but the other points are substantially the same. A variable voltage source is connected between a source and a back gate of each of the current compensation transistors 57_1, . . . , 57_k, as compared to the current compensation transistors 53_1, . . . , 53_k. Accordingly, it is possible to form the current compensation transistors 57_1, . . . , 57_k to have a threshold voltage that is further lower than that of the current compensation transistors 55_1, . . . , 55_k in a case in which the voltage of the variable voltage source is the same.

The compensation current generation circuits 50A to 50C are also formed such that a relationship with the leakage current IL35 is satisfied, similarly to the compensation current generation circuit 50. Here, assuming that currents flowing through the current compensation transistors 53_1, . . . , 53_k are I31, . . . , I3k, respectively, the compensation current generation circuit 50A is formed such that the following Equation (1-2) obtained by replacing I11, . . . , I1k with I31, . . . , I3k, respectively, in the above-mentioned Equation (1-1) is satisfied.

$$IL 35 = ( n \pm α ) \cdot ( I 31 + … + I 3 k ) \qquad ( 1 - 2 )$$

The compensation current generation circuit 50B and the compensation current generation circuit 50C are similar to the compensation current generation circuit 50 or the compensation current generation circuit 50A. That is, assuming that currents flowing through the current compensation transistors 55_1, . . . , 55_k are I51, . . . , I5k, respectively, and currents flowing through the current compensation transistors 57_1, . . . , 57_k are I71, . . . , I7k, respectively, the compensation current generation circuit 50B and the compensation current generation circuit 50C are formed such that the following Equation (1-3) and Equation (1-4) are satisfied, respectively.

$$IL 35 = ( n \pm α ) \cdot ( I 51 + … + I 5 k ) \qquad ( 1 - 3 )$$

$$IL 35 = ( n \pm α ) \cdot ( I 71 + … + I 7 k ) \qquad ( 1 - 4 )$$

In the at least one embodiment, description has been given of the example in which the variable voltage source is connected between the source and the back gate of each of the current compensation transistors 55_1, . . . , 55_k and the current compensation transistors 57_1, . . . , 57_k, but the present invention is not limited to this example. The variable voltage source may be a constant voltage source for supplying a constant voltage. That is, the voltage source connected between the source and the back gate of each of the current compensation transistors 55_1, . . . , 55_k and the current compensation transistors 57_1, . . . , 57_k is not required to have a voltage adjustment function.

In the at least one embodiment, description has been given of the example in which the switching elements are the switches 52_1, . . . , 52_k, but at least some of the switches 52_1, . . . , 52_k may be fuses.

Further, in the at least one embodiment, the current compensation transistors 51_1, . . . , 51_k, 53_1, . . . , 53_k, 55_1, . . . , 55_k, and 57_1, . . . , 57_k may have different magnitudes of individual drain currents as long as the total sum of the drain currents is the same. As another example, a drain current ratio between each of the current compensation transistors 51_1, 53_1, 55_1, and 57_1 and other current compensation transistors 51_2, . . . , 51_k, 53_2, . . . , 53_k, 55_2, . . . , 55_k, and 57_2, . . . , 57_ k may be set to a multiplier of 1:2, and the current value may be set to be adjustable in 2^{k} steps.

The at least one embodiment and modifications thereof described above are encompassed in the scope and the gist of the invention, and are encompassed in the invention defined in the appended claims and equivalents thereof.

What is claimed is:

1. A semiconductor device, comprising:
a current generation circuit configured to generate a charging current to be supplied to a capacitor connected to a connection terminal; and
a current compensation circuit including a compensation current generation circuit configured to generate a compensation current which compensates for a leakage current from a compensation target element including one terminal connected to a path formed between an output terminal of the current generation circuit and the connection terminal,
the current compensation circuit being configured to supply the compensation current to a point of connection to the path.

2. The semiconductor device according to claim 1,
wherein the compensation current generation circuit includes a plurality of transistors connected in parallel between a first terminal and a second terminal, and
wherein the compensation current generation circuit is formed to have an area smaller than an area of the compensation target element.

3. The semiconductor device according to claim 2, wherein each of the plurality of transistors has a threshold voltage that is equal to or lower than a threshold voltage of the compensation target element.

4. The semiconductor device according to claim 2, wherein each of the plurality of transistors has a threshold voltage that is lower than a threshold voltage of the compensation target element.

5. The semiconductor device according to claim 2, wherein each of the plurality of transistors has a potential difference between a back gate of the each of the plurality of transistors and a source of the each of the plurality of transistors.

6. The semiconductor device according to claim 5, wherein the each of the plurality of transistors includes a constant voltage source including a positive electrode connected to the back gate of the each of the plurality of transistors and a negative electrode connected to the source of the each of the plurality of transistors.

7. The semiconductor device according to claim 5, wherein the each of the plurality of transistors includes a variable voltage source including a positive electrode connected to the back gate of the each of the plurality of transistors and a negative electrode connected to the source of the each of the plurality of transistors.

8. The semiconductor device according to claim 2, wherein each of the plurality of transistors includes a back gate and a source that are connected to each other.

9. The semiconductor device according to claim 1,
wherein the compensation current generation circuit includes a plurality of transistors connected in parallel between a first terminal and a second terminal,
wherein each of the plurality of transistors includes a drain connected to the first terminal of the compensation current generation circuit through a corresponding one of switching elements, a source connected to the second terminal of the compensation current generation circuit, a gate connected to the source of the each of the plurality of transistors, and a back gate, and
wherein at least one of the switching elements is in a closed state.

10. The semiconductor device according to claim 9, wherein each of the switching elements is a fuse or a switch.
